(19) United States
(12) Patent Application Publication
(10) Pub. No.: US 2025/0188589 A1
(43) Pub. Date: Jun. 12, 2025

(54) COATING SOURCE HAVING A REFILL DEVICE

(71) Applicant: SINGULUS TECHNOLOGIES AG, Kahl am Main (DE)

(72) Inventor: Sergiy BORODIN, Aschaffenburg (DE)

(21) Appl. No.: 18/717,419

(22) PCT Filed: Nov. 11, 2022
(86) PCT No.: PCT/EP2022/081586

§ 371 Date: Jun. 6, 2024

(30) Foreign Application Priority Data
Dec. 21, 2021 (DE) 10 2021 006 288.4

(51) Int. Cl. C23C 14/24; C23C 16/448

(52) U.S. Cl. CPC C23C 14/243; C23C 14/246; C23C 16/448

(57) ABSTRACT

The present invention relates to a coating source for a coating plant, a coating plant with such a coating source and a method for coating substrates using such a coating source. Furthermore, the present invention relates to a method for refilling a coating source.

### SUMMARY

The present invention relates to a coating source for a coating plant with a refilling device, a coating plant with such a coating source and a method for coating substrates using such a coating source. Moreover, the present invention relates to a method for refilling a coating source.

When coating large-scale glass substrates or a plurality of Si wafers on a large-scale carrier by means of physical or chemical vapor deposition, for example, coating sources with a crucible are typically used in which the material to be vaporized is heated to such an extent that it vaporizes and is available for coating. Such coating sources are known, for example, from U.S. Pat. No. 6,559,065 B2, JP 2012-216373 A, DE 24 30 653 A1, DE 100 21 530 C1, DE 10 2010 060 292 A1 and U.S. Pat. No. 3,984,585.

The coating material in the crucible is inevitably used up after a certain processing time so that it has to be refilled. For such a refill, the coating process must usually be interrupted and possibly even part of the coating source must be dismantled. Subsequently, it will take some time until a state of equilibrium is reached again in the coating source and the coating process can be resumed. As a matter of course, such interruptions to the coating process are undesirable and costly. In order to avoid such an interruption, DE 10 2010 060 292 A1 proposes a method and an apparatus for the continuous coating of substrates. In this method, it should be possible to fill the crucible with semiconductor material during deposition and/or vaporisation. For this purpose, the CSS reactor comprises at least one first airlock with an airlock chamber arranged between at least one inlet opening and at least one outlet opening for holding semiconductor material, means for evacuating the airlock and means for transferring semiconductor material from the airlock into the crucible. On closer inspection, however, the solution proposed by DE 10 2010 060 292 A1 is not practicable. For example, it is not comprehensible how the closure for closing the outlet opening of the airlock is to be kept functional under real process conditions.

It is thus an object of the present invention to provide a coating source for a coating plant that is improved in this regard. This problem is solved by the subject matter of the independent claims. Preferred features of the subject matter according to the invention are described in the dependent claims.

Accordingly, the present invention is directed to a coating source for a coating plant, wherein the coating source comprises a crucible for vaporizing coating material and at least one outlet opening for vaporized coating material. The crucible is closed with a lid that is semi-transparent to infrared (IR) radiation and the coating source comprises at least one first IR radiation source outside the closed crucible for heating the crucible and/or the coating material. At least one opening with a closable filler neck is provided in the lid for filling the crucible with coating material. The coating source further comprises at least one refilling device connected to the at least one filler neck in order to introduce coating material into the crucible, wherein the refilling device comprises a storage container for coating material.

The heating of the crucible and/or the coating material according to the invention by means of an external IR radiation source through the semi-transparent lid allows heating the at least one opening in the lid and the closable filler neck adjoining it in such a way that condensation of vaporized coating material in the region of the at least one opening and the adjoining filler neck can be prevented. This can ensure, for example, that the closure of the closable filler neck does not become clogged due to condensed coating material, as is to be expected in DE 10 2010 060 292 A1. Nevertheless, the coating source according to the invention allows refilling of the coating material without opening the vacuum chamber and dismantling the coating source itself.

The lid which is semi-transparent for IR radiation preferably has a mean transmission of at least 5%, more preferably at least 10% and particularly preferably at least 20% over the wavelength range from 0.5 μm to 5.0 μm.

The at least one filler neck is preferably connected to the refilling device in a vacuum-tight manner at a first end and preferably comprises a valve at an opposite second end. The at least one first IR radiation source is preferably arranged to heat this valve. For this purpose, it is further preferred that the filler neck is semi-transparent for IR radiation in the region of the valve, wherein the semi-transparent region for IR radiation preferably has a mean transmission of at least 5%, more preferably of at least 10% and particularly preferably of at least 20% over the wavelength range from 0.5 μm to 5.0 μm.

This is particularly beneficial for ensuring that the valve is heated sufficiently by the IR radiation source to prevent condensation of vaporized coating material. Thus, the valve remains functional even during the coating process and can be used at any time to fill coating material from the storage container of the refill device into the crucible. An additional heating source, in particular an additional IR radiation source between the hot crucible lid and the colder chamber wall, may also be provided for this purpose.

The coating material in the storage container should as a rule be stored at room temperature (or at most at a slightly higher temperature of less than 200° C.). In contrast, the second end of the filler neck will reach temperatures of several hundred ° C. up to 1,000° C. during operation. Ideally, this temperature gradient should decrease over the length of the filler neck. For this purpose, it is preferred that the at least one filler neck consists of a material the thermal conductivity of which is at most 10 W/m·K, more preferably at most 5 W/m·K, and particularly preferably at most 1 W/m·K. A particularly suitable material for the filler neck is quartz glass.

Furthermore, in view of a gas-tight connection of the second end of the filler neck with the opening in the lid of the coating source, it is preferred that the filler neck at the second end and/or in the region of the valve has a thermal expansion coefficient of at most 10.10⁻⁶ K⁻¹, more preferably of at most 3.10⁻⁶ K⁻¹ and particularly preferably of at most 1.10⁻⁶ K⁻¹

Since the valve at the second end of the filler neck, as explained, is located in a possibly very hot environment, it is preferred that the valve is connected to a coupling element which allows the valve to be opened and closed from a distance. Preferably, this coupling element extends through the filler neck. It is further preferred that this coupling element consists of a material the thermal conductivity of which is 10 W/m·K, more preferably at most 5 W/m·K, and particularly preferably at most 1 W/m·K. Quartz glass is a particularly preferred material also for the coupling element.

Preferably, the refilling device comprises a linear vacuum feedthrough, particularly preferably a magnetically coupled vacuum feedthrough, which is mechanically connected to the coupling element.

The refilling device further preferably comprises a valve with which the storage container can be closed in a vacuum-tight manner. Furthermore, a vacuum pump is preferably provided for evacuating the storage container. It is also preferred that the coating source also comprises a source of inert gas which is connected to the valve and is suitable for flooding the storage container. These features allow to minimize the disturbance of the equilibrium within the coating source during refilling. In particular, moisture can be removed from the coating material in the storage container by evacuating the latter. Subsequent flooding of the storage container with inert gas can prevent coating vapor from being sucked out of the crucible into the storage container when the valve at the second end of the filler neck is opened.

The coating source can further comprise a heater for heating the storage container. For example, it may be advantageous to heat the storage container to a temperature of at least 100° C., preferably at least 130° C., to contribute to water desorption of the coating material.

In a particularly preferred embodiment, the storage container comprises a rotary magazine so that refilling via the filler neck can be controlled and metered in a targeted manner by rotating the rotary magazine relative to an opening in the bottom of the storage container.

Depending on the size and geometry of the coating source, it is preferable in view of the most homogeneous possible feeding of the crucible that several openings are provided in the lid, each with a closable filler neck for filling the crucible with coating material, wherein the coating source has a refill device for each opening. In particular, the refill quantity per refill process should always be significantly smaller than the crucible volume. Accordingly, when using a rotary magazine, the refill quantity in one unit of the rotary magazine should be significantly smaller than the corresponding crucible volume.

It is further preferred that the entire refill device can be dismantled from the coating source in order to fill, decontaminate and/or maintain it in a glovebox, for example. It is also conceivable to dispose of the refill device completely after a single use, as its technical setup is simple, it is easily manageable and easy to replace.

Preferably, coating material to be vaporized, more preferably a material having a vaporization temperature of at most 1,000° C. and particularly preferably one or a combination of the following materials is arranged in the storage container: Se, CdTe, CdSe, CdS, Pbl₂, KCl, NaCl, RbF and/or CsCl.

The present invention is further directed to a coating plant with a coating source as described above. The coating plant is preferably adapted to coat substrates from above.

Furthermore, the present invention is directed to a method for coating substrates using a coating source as described above. Accordingly, a substrate to be coated is positioned under the coating source as described above and subsequently the substrate is coated by means of the coating source. The substrate can rest with respect to the coating source during coating or the substrate can be moved with respect to the coating source or vice versa during coating.

The present invention is further directed to a method for refilling a coating source as described above. For this purpose, the crucible of the coating source is first flooded with an inert gas in order to stop the vaporization process. For example, nitrogen can be introduced into the interior of the coating source at a pressure of between 1 mbar and 100 mbar. Preferably, the pressure in the storage container is increased at the same time so that there is pressure equilibrium between the inside of the coating source and the storage container. Subsequently, the valve at the second end of the filler neck can be opened to fill the crucible with coating material. For this purpose, preferably after opening the valve at the second end of the filler neck, coating material is conveyed from the storage container into the filler neck, wherein this conveying can be carried out, for example, by rotating a rotary magazine. The valve at the second end of the filler neck is then closed again and the crucible and/or the coating material is heated up. As soon as all process parameters for production are in the correct range, the coating process can be resumed. To this end, the inert gas is preferably pumped out of the crucible.

Preferably, the coating process is interrupted before the crucible is flooded. The valve at the second end of the filler neck is preferably opened and closed via the coupling element.

The present invention achieves several technical advantages. For example, the operating time of the coating plant is significantly increased by the limited refilling without completely shutting down the plant or by the direct refilling of the coating source without opening the coating chamber or disassembling the coating source. The number of coating sources required can be reduced and before filling, the filling material can be sufficiently degassed and heated to a higher temperature. By reducing the number of coating sources, the coating plant is overall shorter and the number of devices accompanying the coating sources, such as heating, control, process monitoring, etc., is reduced. Contact with hazardous coating materials such as Cd compounds can be minimized and technically planned for in a wider time frame.

In the following, preferred embodiments of the present invention are described in more detail with reference to the Figures. The Figures show:

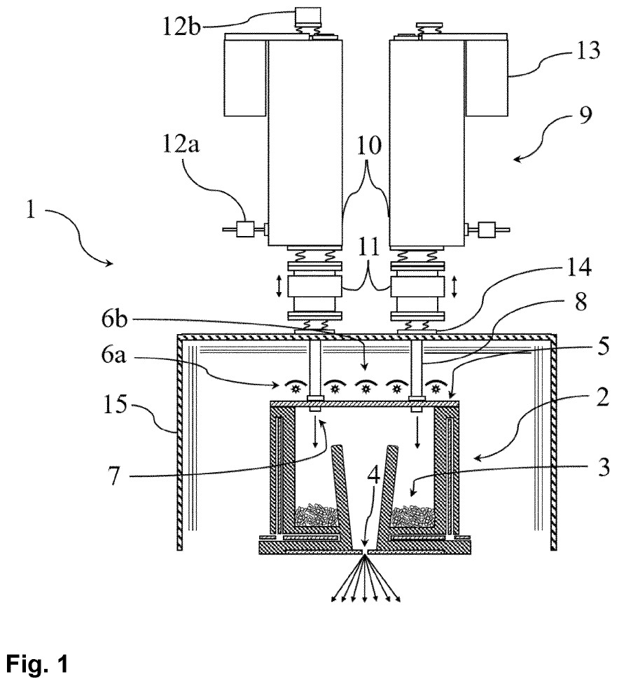

FIG. 1 shows a schematic partial sectional view of a coating source according to a preferred embodiment;

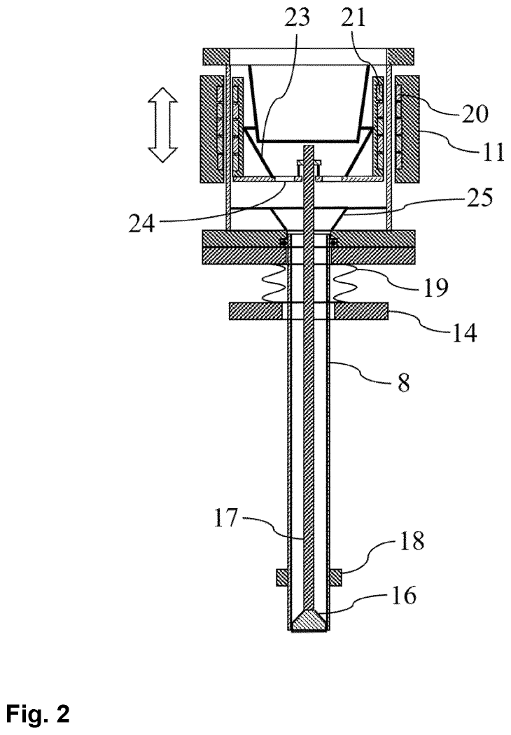

FIG. 2 shows a longitudinal section through the filler neck and the magnetically coupled vacuum feedthrough of a coating source according to a preferred embodiment;

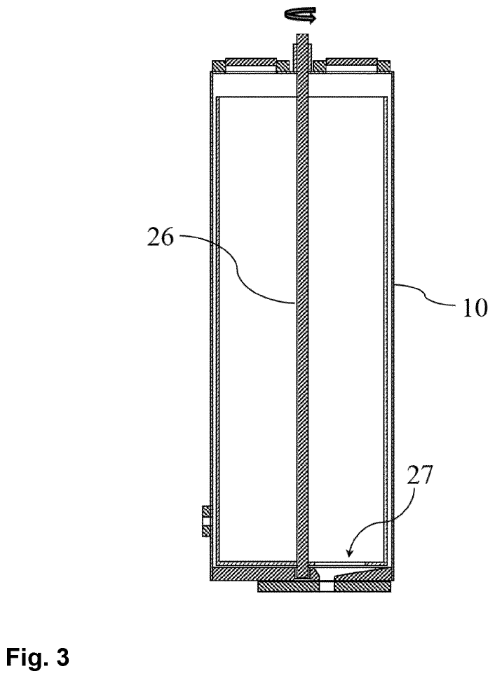

FIG. 3 shows a longitudinal section through a storage container of a coating source according to a preferred embodiment;

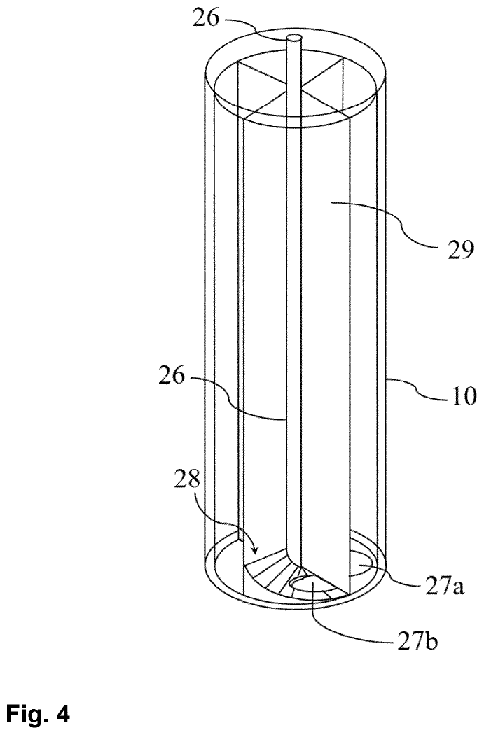

FIG. 4 shows a perspective sectional view through the storage container according to FIG. 3; and

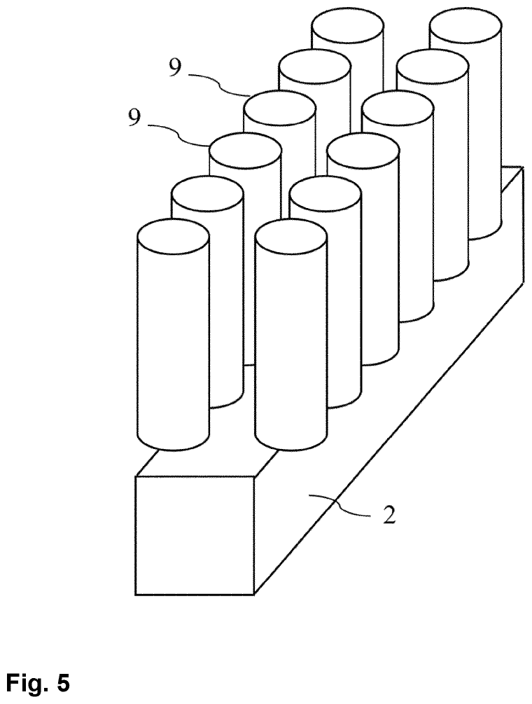

FIG. 5 shows a schematic perspective view of a coating source according to another preferred embodiment.

FIG. 1 schematically shows a coating source 1 for a coating plant according to a preferred embodiment. The coating source 1 comprises a crucible 2 for vaporizing coating material 3 and at least one outlet opening 4 for vaporized coating material, wherein the crucible 2 is closed with a lid 5 that is semi-transparent to IR radiation. The coating source comprises at least one first IR radiation source 6a, 6b outside the closed crucible 2 for heating the crucible 2 and/or the coating material 3, wherein at least one opening 7 with a closable filler neck 8 is provided in the lid 5 for filling the crucible 2 with coating material 3. In the case of the preferred embodiment according to FIG. 1, two such openings 7 with two closable filler necks 8 are provided for filling the crucible. However, there can also be provided significantly more, for example at least 4, at least 6, at least 8 or at least 10 openings with respective filler necks, as schematically indicated in FIG. 5.

FIG. 1 shows a total of five IR radiation sources, of which the four external IR radiation sources 6a are intended for heating the crucible and/or the coating material, whereas the central IR radiation source 6b is primarily used to heat the outlet opening 4. However, this and the specific geometry of the crucible shown in FIG. 1 and other details are not relevant to the present invention. The only decisive factor is the lid 5, which is semi-transparent to IR radiation, with the openings for connection to the closable filler necks.

The coating source 1 further comprises at least one refilling device 9 connected to the at least one filler neck 8 in order to introduce coating material into the crucible 2, wherein the refilling device 9 has a storage container 10 for coating material. In the embodiment according to FIG. 1, two such refilling devices 9 are shown in correspondence with the two openings 7 in the lid 5 and the associated filler neck 8. The refilling devices 9 or, in the illustrated embodiment example, specifically the storage containers 10 each have a valve 12a with which the storage container 10 can be closed in a vacuum-tight manner. The storage container 10 can thus be evacuated with the aid of a vacuum pump not shown. Furthermore, a closable opening 12b can be provided, which can, for example, comprise a separate valve for pumping out. The closable opening 12b can also serve as a viewing window.

The storage container 10 is preferably a rotary magazine, which is shown in detail in FIGS. 3 and 4 and will be explained below. A motor 13 (see FIG. 1) can be provided to rotate said rotary magazine 10.

The magnetically coupled vacuum feedthrough 11 is shown in detail in FIG. 2 and will be explained below. The same applies to the filler neck 8.

The crucible 2 of the coating source is part of a coating chamber 15, only schematically indicated in FIG. 1, to which the refill devices 9 are attached by means of flanges 14.

The filler neck 8 is preferably made of quartz glass or another material with poor thermal conductivity and is firmly mounted on the semi-transparent lid 5 of the crucible 2 via a flange 18 (see FIG. 2). This assembly occurs in a vacuum inside the coating chamber 15. The flexible membrane bellows 19 (see FIG. 2) is used for adjustable adaptation to the crucible position.

At the lower, second end, the filler neck 8 comprises a valve 16, which is semi-transparent to IR radiation and is located in the hot area of the coating source. This prevents the valve from being coated during the substrate coating process. The valve 16 can be opened and closed from the outside by means of the vertically movable feedthrough 17 or the coupling element 17. For this purpose, the upper end of the coupling element 17 is connected to a magnetically coupled vacuum feedthrough 11, which is activated by corresponding magnets 20, 21. Of course, other feedthroughs can also be used instead of the magnetically coupled vacuum feedthrough, e.g. feedthroughs with O-rings or flexible shaft bellows.

The funnels 23 and 25 guide the coating material which, influenced by gravity, falls through the opening 24 into the filler neck 8, so that the coating material can fall through the filler neck 8 and the open valve 16 into the crucible 2. The coupling element can also be tapered towards the valve so that the coating material (e.g. in the form of granules) falling down under gravity does not clog the refill support 8. For example, the outer diameter of the coupling element can decrease by at least 10%, preferably by at least 15%, from the area of the magnetic feedthrough to the region of the valve.

Above the magnetically coupled vacuum feedthrough 11 shown in FIG. 2 is the storage container 10, which in the preferred embodiment shown in FIGS. 3 and 4 is designed as a rotary magazine 10. Said rotary magazine 10 is divided into four compartments by means of four wings 29 and can be rotated about the vertical axis 26 using the rotary drive 13 indicated in FIG. 1. At the lower end, the rotary magazine 10 comprises an opening 27 through which the coating material contained in the storage container can fall into the funnel 23 (see FIG. 2). The feeding of the coating material from one of the compartments in the rotary magazine 10 into the filler neck 8 is metered in that the opening 27b of the corresponding compartment is rotated about the vertical axis 26 in relation to the opening 27a of the base of the rotary magazine 10 until the two openings partially or completely overlap (see FIG. 4). The round opening shape shown is only to be understood as an example. As a matter of course, the openings 27a and 27b can also have an oval or polygonal shape or be designed as a slit, for example. The lower end of each compartment can be formed with a slope 28 to facilitate dispensing and ensure complete emptying of the compartment. The opening 27 in the rotary magazine base can be shaped as a funnel. The quantity of coating material is metered by the number of compartments, the shape of the openings and the rotational speed around the vertical axis 26. The rotary drive can also be equipped with a Maltese cross gear, servo drive or multiphase motor.

1. A coating source for a coating plant, wherein the coating source comprises a crucible for vaporizing coating material and at least one outlet opening for vaporized coating material, wherein the crucible is closed with a lid which is semi-transparent to IR radiation, wherein the coating source comprises at least one first IR radiation source outside the closed crucible for heating the crucible and/or the coating material, wherein at least one opening with a closable filler neck for filling the crucible with coating material is provided in the lid, wherein the coating source further comprises at least one refilling device connected to the at least one filler neck in order to introduce coating material into the crucible, wherein the refilling device comprises a storage container for coating material.

2. The coating source according to claim 1, wherein the at least one filler neck consists of a material the thermal conductivity of which is at most 10 W/m·K.

3. The coating source according to claim 1, wherein the at least one filler neck is connected to the refilling device in a vacuum-tight manner at a first end and comprises a valve at an opposite second end.

4. The coating source according to claim 3, wherein the at least one first IR radiation source is adapted to heat the valve.

5. The coating source according to claim 3, wherein the filler neck is semi-transparent for IR radiation in the region of the valve, wherein the region which is semi-transparent for IR radiation preferably has a mean transmission of at least 5% over the wavelength range of 0.5 μm to 5.0 μm.

6. The coating source according to claim 3, wherein the filler neck at the second end and/or in the region of the valve has a thermal expansion coefficient of at most 10·10⁻⁶ K⁻¹.

7. The coating source according to claim 3, further comprising a coupling element which is connected to the valve and allows the valve to be opened and closed.

8. The coating source according to claim 7, wherein the coupling element extends through the filler neck and/or consists of a material, the thermal conductivity of which is at most 10 W/m·K.

9. The coating source according to claim 7, wherein the refilling device comprises a magnetically coupled vacuum feedthrough, which is mechanically connected to the coupling element.

10. The coating source according to claim 1, wherein the lid which is semi-transparent for IR radiation has a mean transmission of at least 5% over the wavelength range from 0.5 μm to 5.0 μm.

11. The coating source according to claim 1, wherein the refilling device comprises a valve by means of which the storage container can be closed in a vacuum-tight manner.

12. The coating source according to claim 11, further comprising a vacuum pump for evacuating the storage container.

13. The coating source according to claim 11, further comprising a source for inert gas which is connected to the valve for flooding the storage container.

14. The coating source according to claim 1, further comprising a heater for heating the storage container.

15. The coating source according to claim 1, wherein the storage container comprises a rotary magazine.

16. The coating source according to claim 1, wherein in the lid a plurality of openings is provided, each having a closable filler neck for filling the crucible with coating material, wherein the coating source comprises a refilling device for each opening.

17. The coating source according to claim 1, wherein the coating material to be vaporized has a vaporization temperature of at most 1,000° C.

18. A coating plant comprising a coating source according to claim 1.

19. (canceled)

20. A method for coating substrates using a coating source according to claim 1, wherein the method comprises:
positioning a substrate to be coated under the coating source and coating the substrate using the coating source.

21.-22. (canceled)

23. A method for refilling a coating source according to claim 1, wherein the method comprises:
flooding the crucible of the coating source with an inert gas;
opening the valve at the second end of the filler neck to refill the crucible with the coating material;
closing the valve at the second end of the filler neck;
heating the crucible and/or the coating material;
pumping the inert gas out of the crucible; and
resuming the coating process.

24.-27. (canceled)
